(19) United States
(12) Patent Application Publication
(10) Pub. No.: US 2013/0240897 A1
(43) Pub. Date: Sep. 19, 2013

(54) SEMICONDUCTOR DEVICE AND METHOD OF MANUFACTURING THE SAME

(71) Applicant: FUJITSU LIMITED, Kawasaki-shi (JP)

(72) Inventor: Tadahiro IMADA, Kawasaki (JP)

(73) Assignee: FUJITSU LIMITED, Kawasaki-shi (JP)

(21) Appl. No.: 13/758,078

(22) Filed: Feb. 4, 2013

(30) Foreign Application Priority Data
Mar. 19, 2012 (JP) 2012-062901

(51) Int. Cl. H01L 29/778; H01L 29/66; H01L 29/20

(52) U.S. Cl. CPC H01L 29/778; H01L 29/2003; H01L 29/66431
USPC 257/76; 257/194; 438/172

(57) ABSTRACT

A semiconductor device includes a first semiconductor layer formed over a substrate; a second semiconductor layer formed over the first semiconductor layer; electrodes formed over the second semiconductor layer; and a third semiconductor layer formed on the second semiconductor layer; wherein the third semiconductor layer is formed so as to surround each element, in which the electrodes are formed, and wherein the third semiconductor layer is a semiconductor layer of a conductivity type whose polarity is opposite to that of carriers produced in the first semiconductor layer.

### CROSS-REFERENCE TO RELATED APPLICATION

This application is based upon and claims the benefit of priority of the prior Japanese Patent Application No. 2012-062901, filed on Mar. 19, 2012, the entire contents of which are incorporated herein by reference.

### FIELD

The embodiments discussed herein are related to semiconductor devices and their manufacturing methods.

### BACKGROUND

Nitride semiconductors like GaN, AlN, InN, or materials composed from mixed crystals of these nitride semiconductors, or the like have wide band gaps, and are used for high power devices, short wavelength light emitting devices, etc. For example, GaN is one of the nitride semiconductors, and has a band gap of 3.4 eV, which is larger than the Si band gap of 1.1 eV and the GaAs band gap of 1.4 eV.

Such high power devices include field effect transistors (FET), and more specifically, high electron mobility transistors (HEMT). HEMTs using such nitride semiconductors are being used for high power and high efficiency amplifiers, high power switching devices, etc. More specifically, in a HEMT that employs AlGaN for an electron supply layer and GaN for a channel layer, piezoelectric polarization and spontaneous polarization are induced in AlGaN due to a difference in lattice constant between AlGaN and GaN, and a highly concentrated two-dimensional electron gas (2DEG) is produced. Accordingly, this HEMT may be operable at high voltage, and may be used for high efficiency switching elements, high withstand voltage devices for electric vehicles, or the like.

The followings are reference documents.
[Document 1] Japanese Laid-open Patent Publication No. 2010-153493,
[Document 2] Japanese Laid-open Patent Publication No. 2009-49288, and
[Document 3] Japanese Laid-open Patent Publication No. 7-153938.

### SUMMARY

According to an aspect of the invention, a semiconductor device includes a first semiconductor layer formed over a substrate; a second semiconductor layer formed over the first semiconductor layer; electrodes formed over the second semiconductor layer; and a third semiconductor layer formed on the second semiconductor layer; wherein the third semiconductor layer is formed so as to surround each element, in which the electrodes are formed, and wherein the third semiconductor layer is a semiconductor layer of a conductivity type whose polarity is opposite to that of carriers produced in the first semiconductor layer.

The object and advantages of the invention will be realized and attained by means of the elements and combinations particularly pointed out in the claims.

It is to be understood that both the foregoing general description and the following detailed description are exemplary and explanatory and are not restrictive of the invention, as claimed.

### BRIEF DESCRIPTION OF DRAWINGS

FIG. 1 is a structure diagram of a conventional semiconductor device;

FIG. 2 is a top view of a semiconductor device according to a first embodiment;

FIG. 3 is a structure diagram of a semiconductor device according to the first embodiment;

FIG. 4 is an explanatory diagram of a semiconductor device according to the first embodiment;

FIGS. 5A-5C are process diagrams (1) for a manufacturing method of a semiconductor device according to the first embodiment;

FIGS. 6A and 6B are process diagrams (2) for the manufacturing method of a semiconductor device according to the first embodiment;

FIG. 7 is a correlation diagram for elapsed time and an electric current observed in tests performed by applying a voltage to semiconductor devices;

FIGS. 8A-8C are process diagrams (1) for a manufacturing method of a semiconductor device according to a second embodiment;

FIGS. 9A-9C are process diagrams (2) for the manufacturing method of a semiconductor device according to the second embodiment;

FIG. 10 is a structure diagram of a semiconductor device according to a third embodiment;

FIGS. 11A-11C are process diagrams (1) for a manufacturing method of a semiconductor device according to the third embodiment;

FIGS. 12A and 12B are process diagrams (2) for the manufacturing method of a semiconductor device according to the third embodiment;

FIG. 13 is a top view of a semiconductor device according to a fourth embodiment;

FIG. 14 is a structure diagram of a semiconductor device according to the fourth embodiment;

FIG. 15 is an explanatory diagram of a semiconductor device according to the fourth embodiment;

FIGS. 16A-16C are process diagrams (1) for a manufacturing method of a semiconductor device according to the fourth embodiment;

FIGS. 17A and 17B are process diagrams (2) for the manufacturing method of a semiconductor device according to the fourth embodiment;

FIG. 18 is an explanatory diagram (1) of a packaged semiconductor device according to a fifth embodiment;

FIG. 19 is an explanatory diagram (2) of a package semiconductor device according to the fifth embodiment;

FIG. 20 is a circuit diagram of a PFC circuit according to the fifth embodiment;

FIG. 21 is a circuit diagram of a power supply apparatus according to the fifth embodiment; and

FIG. 22 is a structure diagram of a high power amplifier according to the fifth embodiment.

### DESCRIPTION OF EMBODIMENTS

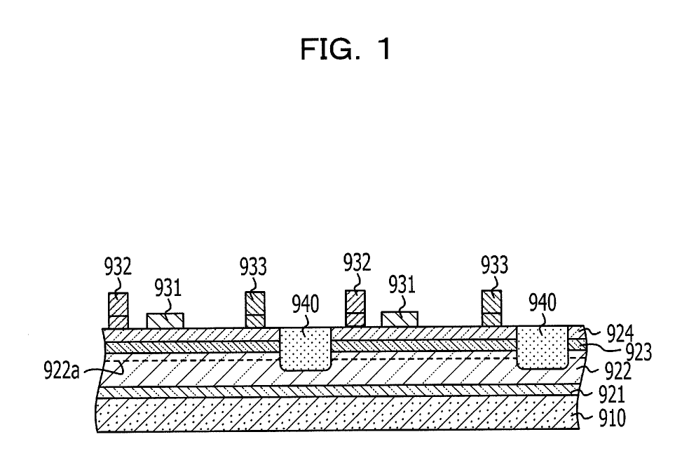

For high withstand-voltage devices, it is desirable to have an element isolation as is a case with devices that employ a typical semiconductor material such as silicon or the like. However, when an element isolation region is formed by ion implantation or by using an insulation material as is the case with devices that employ a typical semiconductor material such as silicon or the like, there is a problem such that a nitride semiconductor material such as GaN or the like may be damaged and this damaged material may cause its crystallinity and insulation break down voltage to decrease. This will be described below with reference to FIG. 1.

FIG. 1 illustrates a HEMT employing a nitride semiconductor material, in which element isolation regions are formed by the ion implantation that is a conventional method. Specifically, the device illustrated in FIG. 1 is composed of nitride semiconductor materials and formed by layering a buffer layer 921, an electron channel layer 922, an intermediate layer 923, an electron supply layer 924, etc., on a substrate 910 composed of silicon or the like. The buffer layer 921 is composed of AlN, the electron channel layer 922 is composed of i-GaN, the intermediate layer 923 is composed of i-AlGaN, and the electron supply layer 924 is composed of n-AlGaN. According to the above, a 2DEG 922a is produced in the intermediate layer 923 or the electron channel layer 922 near an interface with the electron supply layer 924. Furthermore, gate electrodes 931, source electrodes 932, and drain electrodes 933 are formed on the electron supply layer 924. Still furthermore, element isolation regions 940 are formed on the electron supply layer 924 to isolate elements from each other.

The element isolation region 940 may be formed, for example, by injecting Ar ions with an acceleration voltage of 100 keV and a dose amount of 1×10¹⁴ cm⁻² so as to have a predetermined Ar concentration in a region where the element isolation region 940 may be formed. Accordingly, the regions into which Ar ions have been injected become the element isolation regions 940 and enable to electrically isolate the elements from each other. In this method of forming the element isolation regions 940, the Ar ion injection causes damages in the electron channel layer 922 and the like, and leads to lower crystalline quality of the nitride semiconductor layers, a lower insulation break down voltage, and a higher leakage current. This may cause lowering of electrical characteristics and/or reliability of the semiconductor device. Furthermore, in a method of forming the element isolation regions by burying an insulation material, the nitride semiconductor layers are removed by dry etching or the like when forming the element isolation regions. Thus, the electron channel layer 922 and the like may be damaged and a similar problem may also occur.

Hereinafter, embodiments will be described. Note that like reference numerals denote like elements, and the descriptions thereof are omitted.

### First Embodiment

Semiconductor Device

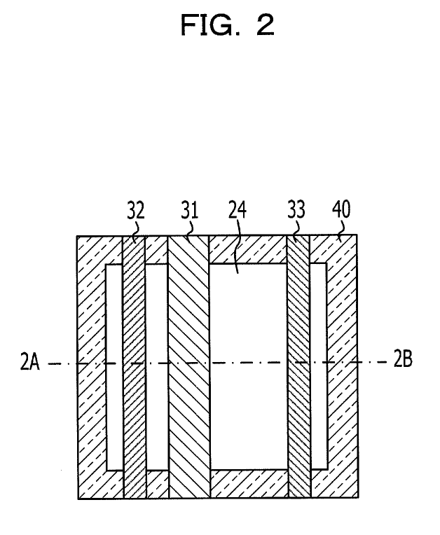

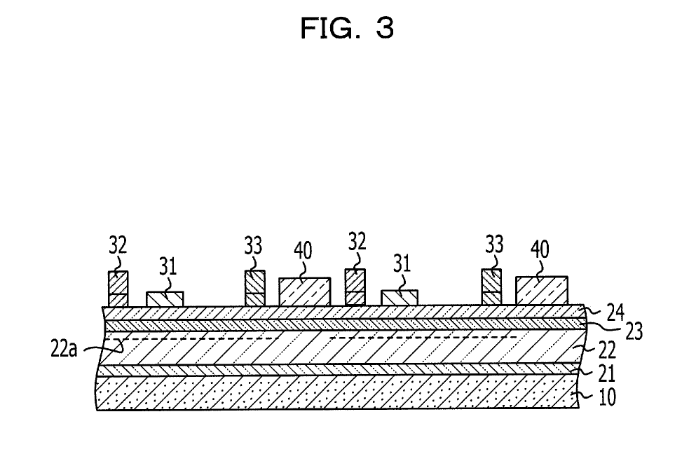

A semiconductor device according to a first embodiment is described with reference to FIG. 2 and FIG. 3. FIG. 2 is a top view of a semiconductor device according to the present embodiment. FIG. 3 is a cross sectional diagram including a cross section cut along a dashed-dotted line 2A-2B in FIG. 2. In the semiconductor device according to the present embodiment, a plurality of transistors (elements) called HEMTs are formed. This semiconductor device is composed of nitride semiconductor materials. In the semiconductor device, a buffer layer 21, an electron channel layer 22, an intermediate layer 23, an electron supply layer 24, etc., are formed on a silicon substrate 10 or the like. The buffer layer 21 is composed of AlN or the like. The electron channel layer 22 is composed of i-GaN or the like. The intermediate layer 23 is composed of i-AlGaN or the like. The electron supply layer 24 is composed of n-AlGaN or the like. According to the above, a 2DEG 22a is produced in the intermediate layer 23 or in the electron channel layer 22 near an interface with the electron supply layer 24. The 2DEG 22a produced in this way is caused by a difference in lattice constant between the electron channel layer 22 composed of GaN and the electron supply layer 24 composed of AlGaN, etc. Alternatively, the semiconductor device according to the present embodiment may also have a structure in which a cap layer (not illustrated) is additionally formed on the electron supply layer 24.

In the above semiconductor device, silicon is used for the substrate 10. However, in addition to silicon, other materials such as, but not limited to, sapphire, GaAs, SiC, GaN may also be used to form the substrate. The material forming the substrate 10 may be a semi-insulating material or an electrically conductive material.

In the semiconductor device of the present embodiment, gate electrodes 31, source electrodes 32, and drain electrodes 33 are formed on the electron supply layer 24, and furthermore, an isolation region formation layer 40 composed of p-GaN is formed to isolate the elements from each other. The isolation region formation layer 40 is formed on the electron supply layer 24 at a region where an element isolation region may be formed in a conventional art. Forming the p-GaN isolation region formation layer 40 enables to cause the 2DEG 22a to disappear from a region directly below the isolation region formation layer 40. In other words, the isolation region formation layer 40 is formed so as to surround each of the elements, and forming the isolation region formation layer 40 in this way and causing the 2DEG 22a to disappear from the region directly below the isolation region formation layer 40 allow achieving the isolation of each element. In the foregoing semiconductor device, the 2DEG 22a is formed in the electron channel layer 22, etc.

Thus, in operation, electrons work as the carriers. Accordingly, the isolation region formation layer 40 is composed of p-type semiconductor, namely p-GaN. However, in a case where the semiconductor device is operated with hole carriers, the isolation region formation layer 40 in the semiconductor device of the present embodiment may be an n-type semiconductor layer or composed of n-type semiconductor. In the present embodiment, the electron channel layer 22, the electron supply layer 24, and the isolation region formation layer 40 may be alternatively referred to as a first semiconductor layer, a second semiconductor layer, and a third semiconductor layer, respectively.

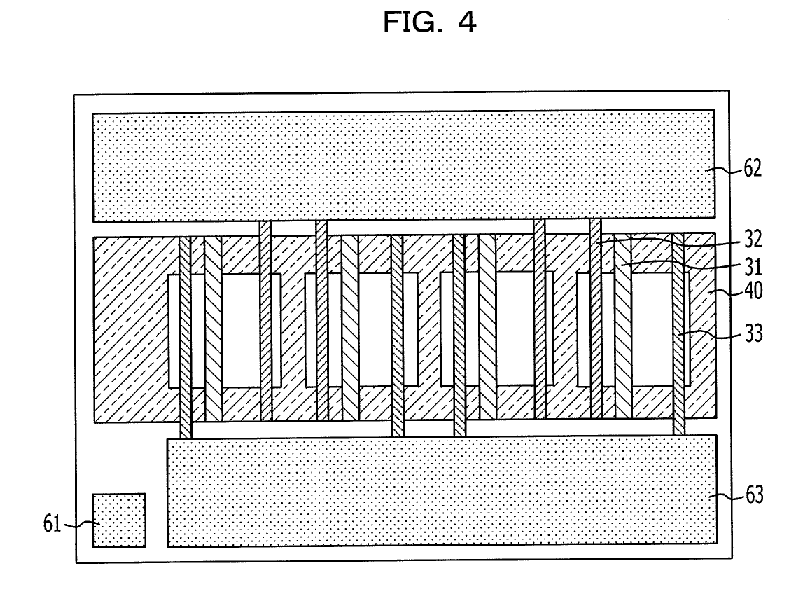

FIG. 4 illustrates a semiconductor device according to the present embodiment, in which a plurality of HEMT (elements) are formed. The isolation region formation layer 40 is formed between the elements, and the 2DEG is caused to disappear from a region directly below the isolation region formation layer 40. Thus, the isolation of each element is achieved. In each of the HEMTs (elements), the source electrode 32 is connected to a source electrode pad 62, the drain electrode 33 is connected to a drain electrode pad 63, and the gate electrode 31 is connected to a gate electrode pad 61 through wiring (not illustrated) or the like.

Manufacturing Method of Semiconductor Device

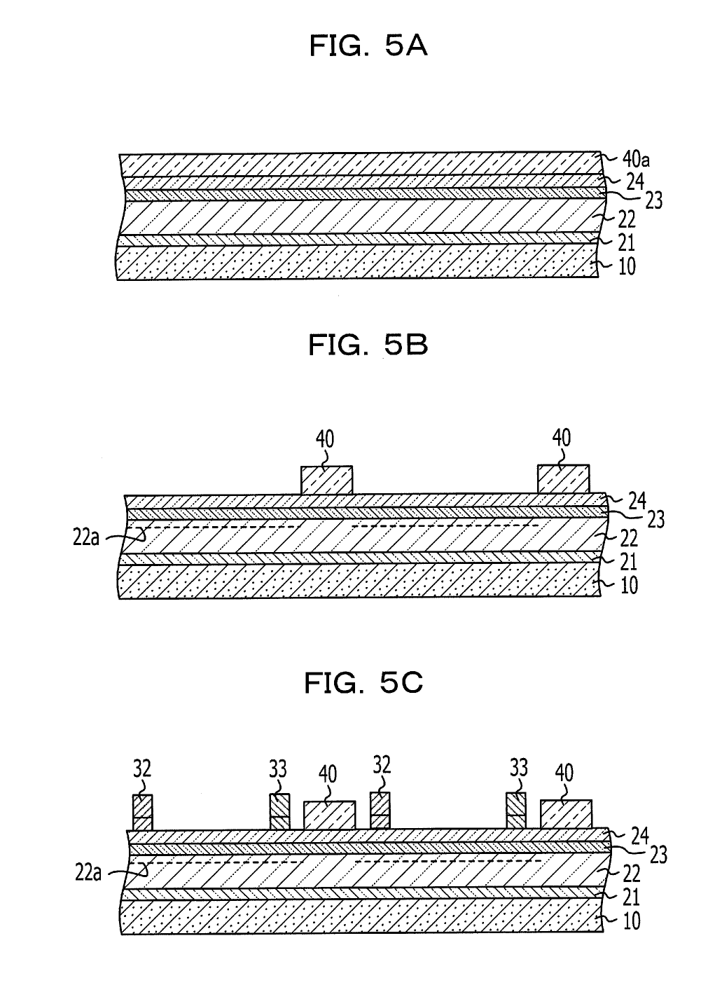

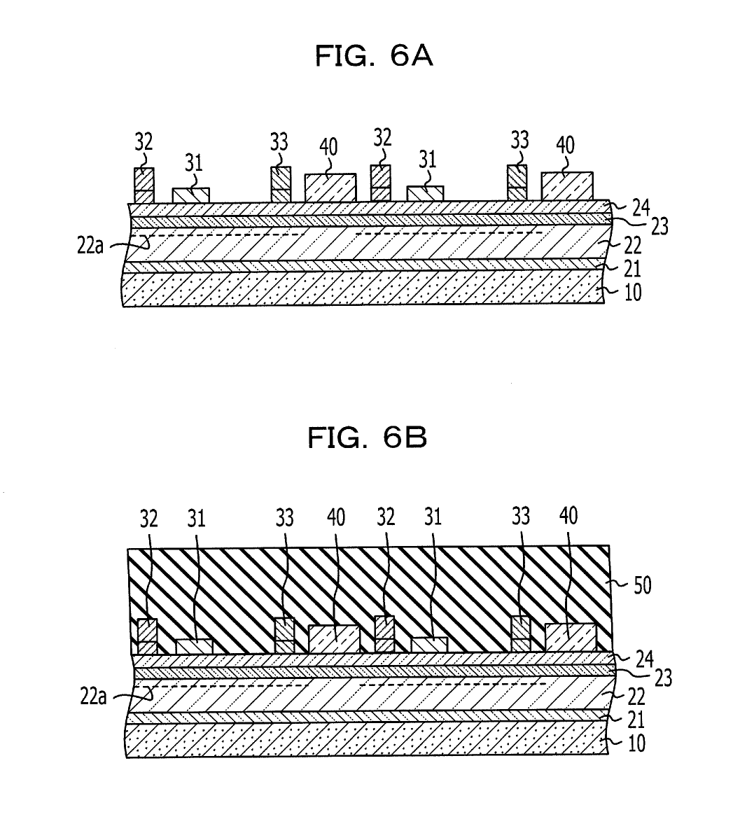

Next, a method of manufacturing a semiconductor device according to the present embodiment is described with reference to FIG. 5 and FIG. 6.

First, as illustrated in FIG. 5A, nitride semiconductor layers are formed on the substrate 10 by metal-organic vapor phase epitaxy (MOVPE) technique. This nitride semiconductor layers may include, but are not limited to, the buffer layer 21, the electron channel layer 22, the intermediate layer 23, the electron supply layer 24, and an isolation region formation film 40a. These nitride semiconductor layers are epitaxially grown by MOVPE. Alternatively, a method other than MOVPE such as, for example, a molecular beam epitaxy (MBE) technique may be used. A silicon substrate is used for the substrate 10. The buffer layer 21 is composed of AlN with a thickness of 0.1 μm. The electron channel layer 22 is composed of i-GaN with a thickness of 3 μm. The intermediate layer 23 is composed of i-AlGaN with a thickness of 5 nm. The electron supply layer 24 is composed of n-AlGaN with a thickness of 30 nm. The isolation region formation film 40a is composed of p-GaN with a thickness of 10 nm. The isolation region formation film 40a is formed to form the isolation region formation layer 40, which will be described below. In an alternative structure, a cap layer (not illustrated) may be additionally formed on the electron supply layer 24.

In the present embodiment, when forming AlN, GaN, and AlGaN by MOVPE, gases such as, but not limited to, trimethylaluminium (TMA) that serves as an Al source, trimethylgallium (TMG) that serves as a Ga source, and ammonia (NH₃) that serves as a N source are used as source material gases. Layers of AlN, GaN, and AlGaN, which are nitride semiconductor layers, may be deposited by supplying the foregoing source material gases that are mixed in predetermined proportions corresponding to a composition of the nitride semiconductor layer to be deposited. For the semiconductor device according to the present embodiment, when forming the nitride semiconductor layers by MOVPE, a flow rate of the ammonia gas is 100 ccm-10 LM, an internal pressure of deposition chamber during the deposition is 50-300 torr, and a growth temperature is 1000-1200° C.

Si is used as n-type impurity to dope n-AlGaN that becomes the electron supply layer 24. Specifically, when depositing the electron supply layer 24, SiH₄ gas is added to the source material gases with a preset flow rate so as to form the Si-doped electron supply layer 24. The concentration of the doped Si in the n-AlGaN formed as described above ranges from 1×10¹⁸ cm⁻³ to 1×10²⁰ cm⁻³, and may be about 5×10¹⁸ cm⁻³, for example. A method similar to the above may be employed even in a case where n-GaN or the like is deposited as the cap layer (not illustrated).

Mg is used as p-type impurity to dope p-GaN that becomes the isolation region formation film 40a. The concentration of the doped Mg ranges from 1×10²⁰ to 1×10²² cm⁻³, and may be, for example, about 1×10²¹ cm⁻³. Annealing is performed for activation after the deposition of the isolation region formation film 40a.

Next, as illustrated in FIG. 5B, the isolation region formation layer 40 for the element isolation is formed from this p-GaN. Specifically, the isolation region formation film 40a is coated with photoresist and then subjected to exposure processing with a photolithography apparatus and development processing, thereby forming a resist pattern (not illustrated) on regions where the isolation region formation layer 40 may be formed. Subsequently, dry etching such as a reactive ion etching (RIE) or the like is performed to remove portions of the isolation region formation film 40a at which no resist pattern is formed, thereby forming the p-GaN isolation region formation layer 40. Subsequently, the resist pattern (not illustrate) is removed with an organic solvent or the like.

Next, as illustrated in FIG. 5C, the source electrodes 32 and the drain electrodes 33 are formed on the electron supply layer 24. Specifically, the electron supply layer 24 and the isolation region formation layer 40 are coated with photoresist, and then subjected to exposure processing with a photolithography apparatus and development processing, thereby forming a resist pattern (not illustrated) in which openings are formed at regions where the source electrodes 32 and the drain electrodes 33 may be formed. Subsequently, a metal film for forming the source electrodes 32 and the drain electrodes 33 is deposited by vacuum deposition, and then dipped into an organic solvent or the like to remove the metal film deposited on the resist pattern as well as the resist pattern itself by liftoff. The remaining portions of the metal film form the source electrodes 32 and the drain electrodes 33.

Next, as illustrated in FIG. 6A, the gate electrodes 31 are each formed on the electron supply layer 24 between the source electrode 32 and the drain electrode 33. Specifically, the electron supply layer 24 and the isolation region formation layer 40 are coated with photoresist, and then subjected to exposure processing with a photolithography apparatus and development processing, thereby forming a resist pattern (not illustrated) in which openings are formed at regions where the gate electrodes 31 may be formed. Subsequently, a metal film for forming the gate electrodes 31 is deposited by vacuum deposition, and then dipped into an organic solvent or the like to remove the metal film deposited on the resist pattern as well as the resist pattern itself by liftoff. The remaining portions of the metal film form the gate electrodes 31.

Next, as illustrated in FIG. 6B, an insulation film 50 is formed on the electron supply layer 24, the gate electrodes 31, the source electrodes 32, the drain electrodes 33, and the isolation region formation layer 40. The insulation film 50 is a film that becomes a passivation film, and composed of an insulation material such as SiO₂, SiN or the like. The insulation film 50 is formed by plasma chemical vapor deposition (CVD) or the like.

Thus, a semiconductor device may be manufactured according to the manufacturing method of semiconductor device according to the present embodiment.

Experimental Results

Next, results of stress test will be described. The stress test has been conducted for a semiconductor device according to the present embodiment and a semiconductor device having a conventional structure. As the semiconductor device according to the present embodiment, a semiconductor device having the structure illustrated in FIG. 3 was manufactured. As the semiconductor device having a conventional structure, a semiconductor device having the structure illustrated in FIG. 1 was manufactured. For the semiconductor device according to the present embodiment, a voltage of 600 V was applied between the source electrode 32 and the drain electrode 33 with having the isolation region formation layer 40 in between, namely between the source electrode 32 of one element and the drain electrode 33 of the adjacent element that is disposed at the other side of the isolation region formation layer 40, and an amount of a current flowing therebetween was measured.

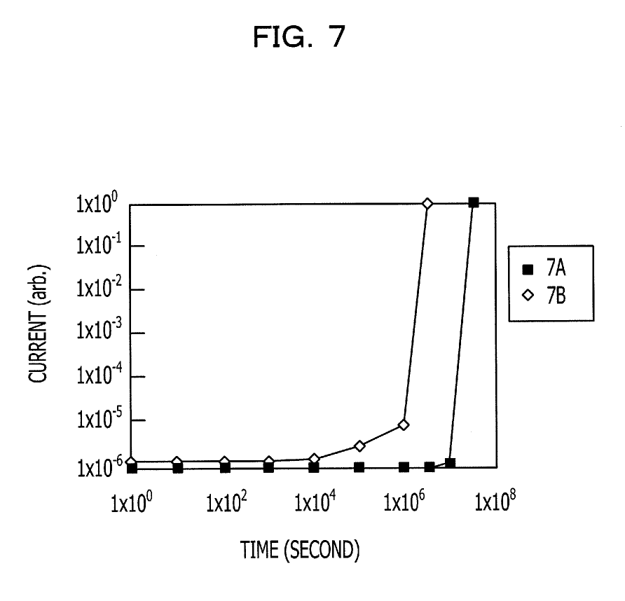

For the semiconductor device having the conventional structure illustrated in FIG. 1, a voltage of 600 V was applied between the source electrode 932 and the drain electrode 933 with having the element isolation region 940 in between, and an amount of a current flowing therebetween was measured. FIG. 7 illustrates the results. FIG. 7 illustrates measurement results of the current flow amount over time. The measurements were made on the top surface where the isolation region formation layer 40 had a width of 5 μm and an ambient temperature was 200° C. In FIG. 7, reference numeral 7A denotes characteristics of the semiconductor device according to the present embodiment, whereas reference numeral 7B denotes the characteristics of the semiconductor device having the conventional structure. The breakdown started from 1×10⁷ seconds in the semiconductor device according to the present embodiment that is denoted by reference numeral 7A, whereas the breakdown started from 1×10⁶ seconds in the semiconductor device having the conventional structure denoted by reference numeral 7B. The start time of the breakdown in the present embodiment is about an order of magnitude longer than that of the conventional structure.

As described above, it takes a longer time for the semiconductor device according to the present embodiment to start to break down. Thus, the semiconductor device according to the present embodiment is more resistant to breakdown, and has higher reliability, compared to the semiconductor device having the conventional structure. Furthermore, the leak current is smaller in the semiconductor device according to the present embodiment, which is denoted by reference numeral 7A, compared to the semiconductor device having the conventional structure, which is denoted by reference numeral 7B.

Accordingly, the semiconductor device according to the present embodiment was more resistant to breakdown and had a smaller leak current compared to the semiconductor device having the conventional structure. It is inferred that such features of the present embodiment may be realized because the element isolation is achieved without causing any damage to the nitride semiconductor layers.

### Second Embodiment

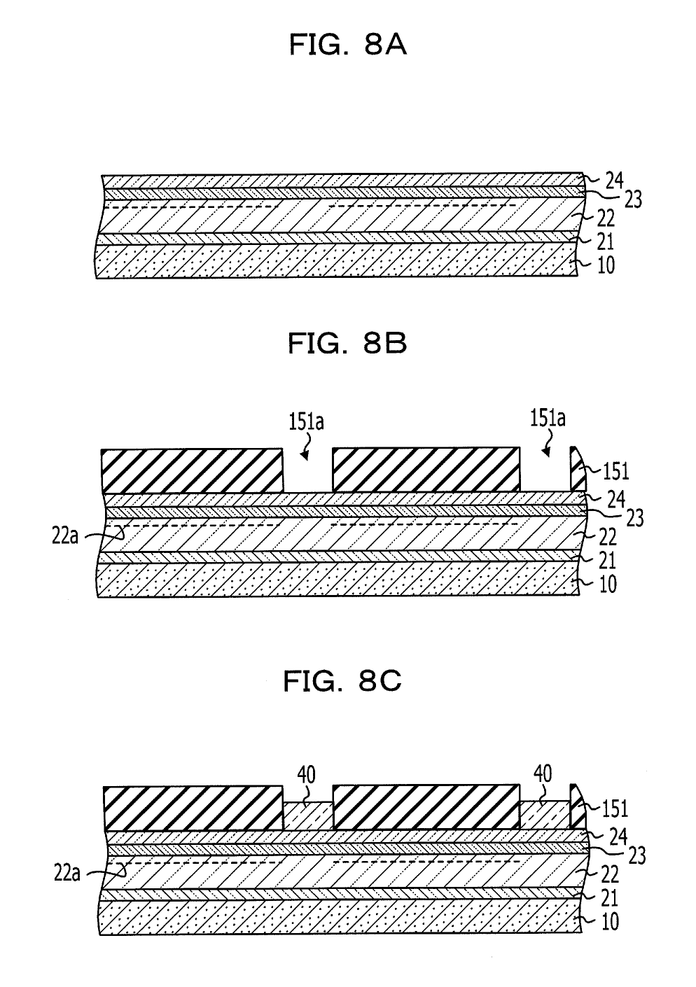

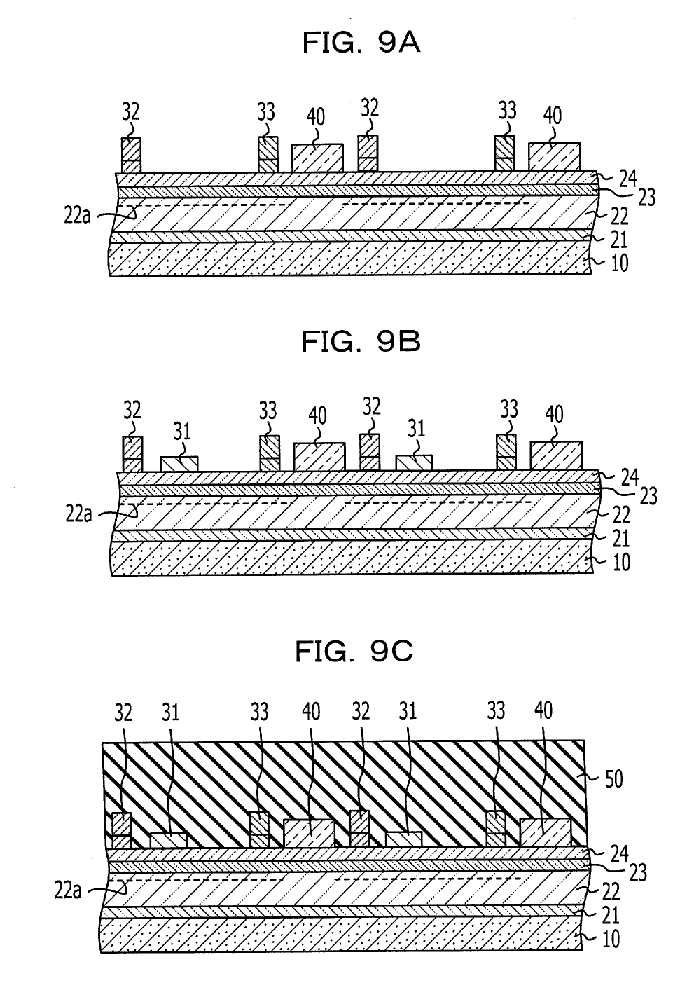

Next, the second embodiment is described. The present embodiment relates to a manufacturing method of the semiconductor device according to the first embodiment, and is a manufacturing method different from that of the first embodiment. The manufacturing method of semiconductor device according to the present embodiment is described with reference to FIG. 8 and FIG. 9.

First, as illustrated in FIG. 8A, nitride semiconductor layers are formed on the substrate 10 by MOVPE technique. This nitride semiconductor layers may include, but are not limited to, the buffer layer 21, the electron channel layer 22, the intermediate layer 23, and the electron supply layer 24. The nitride semiconductor layers are epitaxially grown by MOVPE. Alternatively, a method other than MOVPE such as, for example, a MBE technique may be used. A silicon substrate is used for the substrate 10. The buffer layer 21 is composed of AlN with a thickness of 0.1 μm. The electron channel layer 22 is composed of i-GaN with a thickness of 3 μm. The intermediate layer 23 is composed of i-AlGaN with a thickness of 5 nm. The electron supply layer 24 is composed of n-AlGaN with a thickness of 30 nm. In an alternative structure, a cap layer (not illustrated) may be additionally formed on the electron supply layer 24.

In the present embodiment, when forming AlN, GaN, and AlGaN by MOVPE, gases such as, but not limited to, trimethylaluminium (TMA) that serves as an Al source, trimethylgallium (TMG) that serves as a Ga source, and ammonia (NH₃) that serves as a N source are used as the source material gases. Layers of AlN, GaN, and AlGaN, which are nitride semiconductor layers, may be deposited by supplying the foregoing source material gases that are mixed in predetermined proportions corresponding to a composition of the nitride semiconductor layer to be deposited. For the semiconductor device according to the present embodiment, when forming the nitride semiconductor layers by MOVPE, a flow rate of the ammonia gas is 100 ccm-10 LM, an internal pressure of deposition chamber during the deposition is 50-300 torr, and a growth temperature is 1000-1200° C.

Si is used as n-type impurity to dope n-AlGaN that becomes the electron supply layer 24. Specifically, when depositing the electron supply layer 24, SiH₄ gas is added to the source material gases with a preset flow rate so as to form the Si-doped electron supply layer 24. The concentration of the doped Si in the n-AlGaN formed as described above ranges from 1×10¹⁸ to 1×10²⁰ cm⁻³, and is, for example, about 5×10¹⁸ cm⁻³. A method similar to the above may be employed even in a case where n-GaN or the like is formed as the cap layer (not illustrated) or the like.

Next, as illustrated in FIG. 8B, a silicon oxide mask 151 is formed. The silicon oxide mask 151 has openings 151a at regions where the isolation region formation layer 40 may be formed. Specifically, a silicon oxide film is deposited on the electron supply layer 24 by plasma CVD or the like. Subsequently, the deposited silicon oxide film is coated with photoresist, and then subjected to exposure processing with a photolithography apparatus and development processing, thereby forming a resist pattern (not illustrated). The resist pattern (not illustrated) formed as described above has openings at portions corresponding to regions where the isolation region formation layer 40 may be formed. Subsequently, dry etching such as RIE or the like is performed to remove portions of the silicon oxide film at regions where no resist pattern is formed. According to the above, the silicon oxide mask 151 having the openings 151a at the regions where the isolation region formation layer 40 may be formed is formed. Subsequently, the resist pattern (not illustrate) is removed with an organic solvent or the like.

Next, as illustrated in FIG. 8C, the isolation region formation layer 40 composed of p-GaN is formed in the openings 151a of the silicon oxide mask 151. Specifically, p-GaN is epitaxially grown by MOCVD on a surface where the silicon oxide mask 151 is formed to form the isolation region formation layer 40. In the p-GaN epitaxial growth, there is crystal growth on a crystal surface where the electron supply layer 24 is exposed whereas there is no crystal growth on an amorphous surface such as the silicon oxide mask 151. That is, the p-GaN epitaxial growth is a selective growth. Thus, the epitaxial growth is allowed to take place only in the opening 151a of the silicon oxide mask 151, making it possible to form the p-GaN isolation region formation layer 40. The isolation region formation layer 40 is composed of p-GaN with a thickness of 10 nm. Mg is used as p-type impurity to dope this p-GaN. The concentration of the doped Mg ranges from 1×10²⁰ to 1×10²² cm⁻³, and may be, for example, about 1×10²¹ cm⁻³. Annealing is performed for activation after the deposition of the isolation region formation layer 40.

Next, as illustrated in FIG. 9A, the source electrodes 32 and the drain electrodes 33 are formed on the electron supply layer 24. Specifically, the electron supply layer 24 and the isolation region formation layer 40 are coated with photoresist, and then subjected to exposure processing with a photolithography apparatus and development processing, thereby forming a resist pattern (not illustrated) in which openings are formed at regions where the source electrodes 32 and the drain electrodes 33 may be formed. Subsequently, a metal film for forming the source electrodes 32 and the drain electrodes 33 is deposited by vacuum deposition, and then dipped into an organic solvent or the like to remove the metal film deposited on the resist pattern as well as the resist pattern itself by liftoff. The remaining portions of the metal film form the source electrodes 32 and the drain electrodes 33.

Next, as illustrated in FIG. 9B, the gate electrodes 31 are each formed on the electron supply layer 24 between the source electrode 32 and the drain electrode 33. Specifically, the electron supply layer 24 and the isolation region formation layer 40 are coated with photoresist, and then subjected to exposure processing with a exposure apparatus and development processing, thereby forming a resist pattern (not illustrated) in which openings are formed at regions where the gate electrodes 31 are formed. Subsequently, a metal film for forming the gate electrodes 31 is deposited by vacuum deposition, and then dipped into an organic solvent or the like to remove the metal film deposited on the resist pattern as well as the resist pattern itself by liftoff. The remaining portions of the metal film form the gate electrodes 31.

Next, as illustrated in FIG. 9C, an insulation film 50 is formed on the electron supply layer 24, the gate electrodes 31, the source electrodes 32, the drain electrodes 33, and the isolation region formation layer 40. The insulation film 50 is a film that becomes a passivation film, and composed of an insulation material such as SiO₂, SiN or the like. The insulation film 50 is formed by plasma CVD or the like.

As described above, a semiconductor device may be manufactured according to the manufacturing method of semiconductor device according to the present embodiment. Except for the matters described above, the present embodiment is substantially the same as the first embodiment.

### Third Embodiment

Semiconductor Device

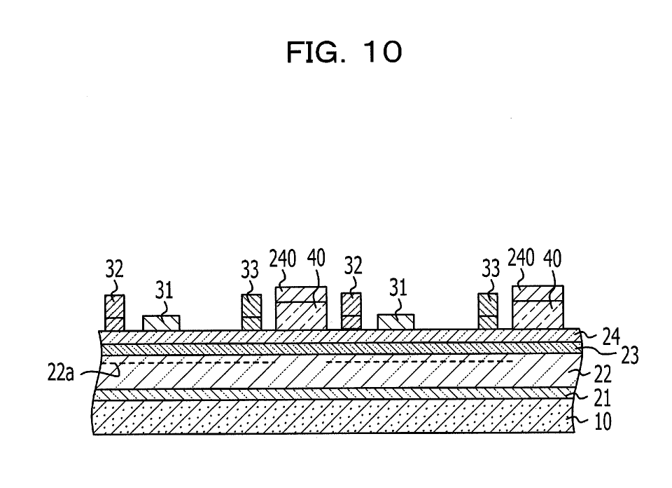

Next, a semiconductor device according to the third embodiment is described with reference to FIG. 10. In the semiconductor device according to the present embodiment, a plurality of transistors (elements) called HEMTs are formed. This semiconductor device is composed of nitride semiconductor materials and formed by layering a buffer layer 21, an electron channel layer 22, an intermediate layer 23, an electron supply layer 24, etc., on a substrate 10 composed of silicon or the like. The buffer layer 21 is composed of AlN or the like. The electron channel layer 22 is composed of i-GaN or the like. The intermediate layer 23 is composed of i-AlGaN or the like. The electron supply layer 24 is composed of n-AlGaN or the like.

According to the above, the 2DEG 22a is produced in the intermediate layer 23 or in the electron channel layer 22 near an interface with the electron supply layer 24. The 2DEG 22a, which is produced in such a way described above, is generated due to a difference in lattice constant between the electron channel layer 22 composed of GaN and the electron supply layer 24 composed of AlGaN, etc. The semiconductor device according to the present embodiment may have an alternative structure in which a cap layer (not illustrated) is additionally formed on the electron supply layer 24.

In the foregoing semiconductor device, silicon is used for the substrate 10. However, in addition to silicon, other materials such as sapphire, GaAs, SiC, GaN, etc. may also be used to form the substrate. The material forming the substrate 10 may be a semi-insulating material or a conductive material.

In the semiconductor device of the present embodiment, gate electrodes 31, source electrodes 32, and drain electrodes 33 are formed on the electron supply layer 24, and furthermore, an isolation region formation layer 40 composed of p-GaN is formed to isolate the elements from each other. Furthermore, isolation region formation electrodes 240 composed of a metal material are formed on the isolation region formation layer 40. A voltage of 0 V or negative potential is applied to the isolation region formation electrodes 240. Such an arrangement enables to cause the 2DEG 22a to disappear from a region directly below the isolation region formation layer 40 with more certainty, making it possible to achieve more reliable element isolation between the elements. In the foregoing semiconductor device, the 2DEG 22a is produced in the electron channel layer 22 or the like. Thus, in operation, electrons work as the carriers. Accordingly, the isolation region formation layer 40 is composed of p-type semiconductor, namely p-GaN. However, in a case where the semiconductor device is operated with hole carriers, the isolation region formation layer 40 in the semiconductor device of the present embodiment may be an n-type semiconductor layer or composed of n-type semiconductor.

Furthermore, even in a case where a high voltage is applied to the semiconductor device according to the present embodiment, a current or the like may be supplied to the isolation region formation electrodes 240 via the isolation region formation layer 40 composed of p-GaN. This arrangement may reduce the possibility of high voltage breakdown of the semiconductor device, and enable to provide long-life reliable semiconductor devices.

Semiconductor Device Manufacturing Method

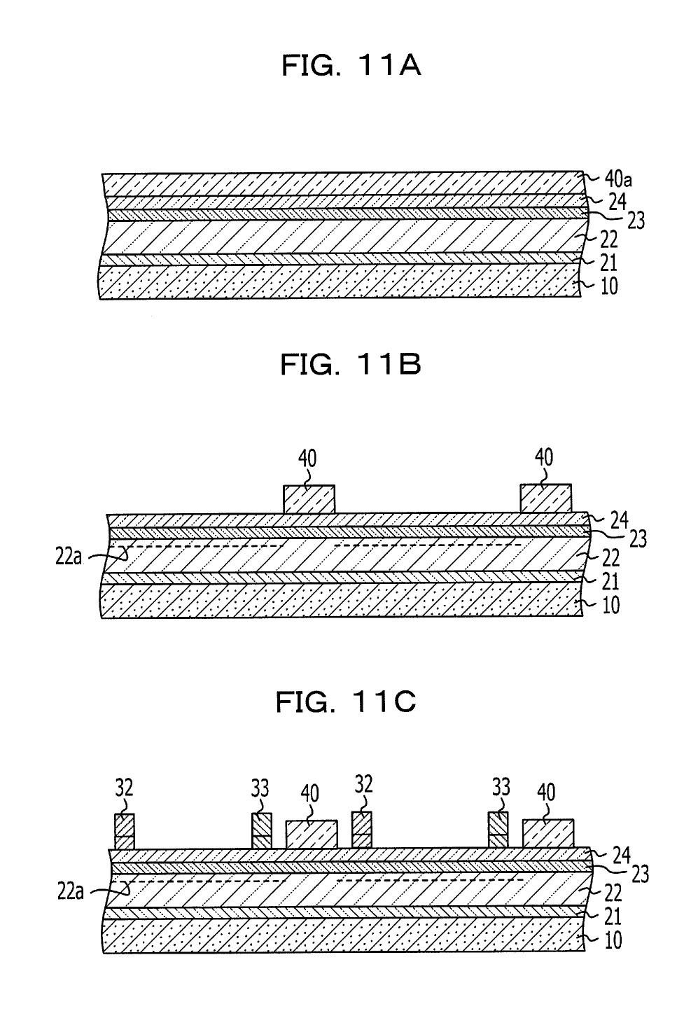

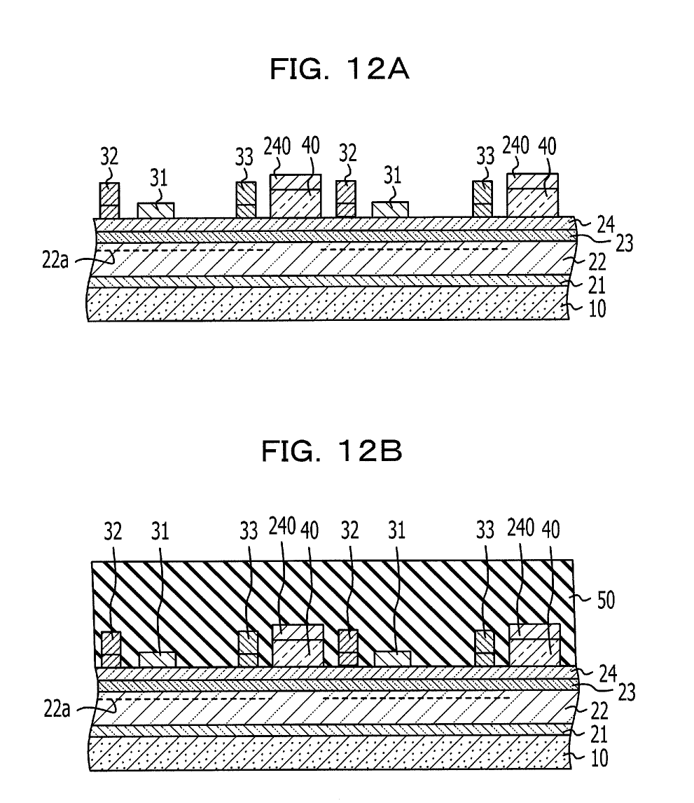

Next, a method of manufacturing the semiconductor device according to the present embodiment is described with reference to FIG. 11 and FIG. 12.

First, as illustrated in FIG. 11A, nitride semiconductor layers are formed on the substrate 10 by MOVPE technique. This nitride semiconductor layers may include, but are not limited to, the buffer layer 21, the electron channel layer 22, the intermediate layer 23, the electron supply layer 24, and an isolation region formation film 40a. The nitride semiconductor layers are epitaxially grown by MOVPE. Alternatively, a method other than MOVPE such as, for example, a MBE technique may be used. A silicon substrate is used for the substrate 10. The buffer layer 21 is composed of AlN with a thickness of 0.1 μm. The electron channel layer 22 is composed of i-GaN with a thickness of 3 μm. The intermediate layer 23 is composed of i-AlGaN with a thickness of 5 nm. The electron supply layer 24 is composed of n-AlGaN with a thickness of 30 nm. The isolation region formation film 40a is composed of p-GaN with a thickness of 10 nm. The isolation region formation film 40a is formed to form the isolation region formation layer 40, which will be described below. In an alternative structure, a cap layer (not illustrated) may be additionally formed on the electron supply layer 24.

In the present embodiment, when forming AlN, GaN, and AlGaN by MOVPE, gases such as, but not limited to, trimethylaluminium (TMA) that serves as an Al source, trimethylgallium (TMG) that serves as a Ga source, and ammonia (NH₃) that serves as a N source are used as source material gases. Layers of AlN, GaN, and AlGaN, which are nitride semiconductor layers, may be deposited by supplying the foregoing source material gases that are mixed in predetermined proportions corresponding to a composition of the nitride semiconductor layer to be deposited. For the semiconductor device according to the present embodiment, when forming the nitride semiconductor layers by MOVPE, a flow rate of the ammonia gas is 100 ccm-10 LM, an internal pressure of deposition chamber during the deposition is 50-300 torr, and a growth temperature is 1000-1200° C.

Si is used as n-type impurity to dope n-AlGaN that becomes the electron supply layer 24. Specifically, when depositing the electron supply layer 24, SiH₄ gas is added to the source material gases with a preset flow rate so as to form the Si-doped electron supply layer 24. The concentration of the doped Si in the n-AlGaN formed as described above ranges from 1×10¹⁸ to 1×10²⁰ cm⁻³, and may be, for example, about 5×10¹⁸ cm⁻³. A method similar to the above may be employed even in a case where n-GaN or the like is deposited as the cap layer (not illustrated).

Mg is used as p-type impurity to dope p-GaN that becomes the isolation region formation film 40a. The concentration of the doped Mg ranges from 1×10²⁰ to 1×10²² cm⁻³, and may be, for example, about 1×10²¹ cm⁻³. Annealing is performed for activation after the deposition of the isolation region formation film 40a.

Next, as illustrated in FIG. 11B, the isolation region formation layer 40 for the element isolation is formed from this p-GaN. Specifically, the isolation region formation film 40a is coated with photoresist, and then subjected to exposure processing with a photolithography apparatus and development processing, thereby forming a resist pattern (not illustrated) on regions where the isolation region formation layer 40 may be formed. Subsequently, dry etching such as RIE or the like is performed to remove portions of the isolation region formation film 40a at which no resist pattern is formed, thereby forming the p-GaN isolation region formation layer 40. Subsequently, the resist pattern (not illustrate) is removed with an organic solvent or the like.

Next, as illustrated in FIG. 11C, the source electrodes 32 and the drain electrodes 33 are formed on the electron supply layer 24. Specifically, the electron supply layer 24 and the isolation region formation layer 40 are coated with photoresist, and then subjected to exposure processing with a photolithography apparatus and development processing, thereby forming a resist pattern (not illustrated) in which openings are formed at regions where the source electrodes 32 and the drain electrodes 33 may be formed. Subsequently, a metal film for forming the source electrodes 32 and the drain electrodes 33 is deposited by vacuum deposition, and then dipped into an organic solvent or the like to remove the metal film deposited on the resist pattern as well as the resist pattern itself by liftoff. The remaining portions of the metal film form the source electrodes 32 and the drain electrodes 33.

Next, as illustrated in FIG. 12A, the gate electrodes 31 are each formed on the electron supply layer 24 between the source electrode 32 and the drain electrode 33, and the isolation region formation electrodes 240 are formed on the isolation region formation layer 40. Specifically, the electron supply layer 24 and the isolation region formation layer 40 are coated with photoresist, and then subjected to exposure processing with a photolithography apparatus and development processing, thereby forming a resist pattern (not illustrated) in which openings are formed at regions where the gate electrodes 31 may be formed and above the isolation region formation layer 40.

Subsequently, a metal film for forming the gate electrodes 31 and the isolation region formation electrodes 240 is deposited by vacuum deposition, and then dipped into an organic solvent or the like to remove the metal film deposited on the resist pattern as well as the resist pattern itself by liftoff. The remaining portions of the metal film form the gate electrodes 31 and the isolation region formation electrodes 240. In the above, the method is described for a case where the gate electrodes 31 and the isolation region formation electrodes 240 are simultaneously formed in the same process step. However, the gate electrodes 31 and the isolation region formation electrodes 240 may also be formed separately in different process steps.

Next, as illustrated in FIG. 12B, an insulation film 50 is formed on the electron supply layer 24, the gate electrodes 31, the source electrodes 32, the drain electrodes 33, and the isolation region formation electrodes 240. The insulation film 50 is a film that becomes a passivation film, and composed of an insulation material such as SiO₂, SiN or the like. The insulation film 50 is formed by plasma CVD or the like.

Thus, a semiconductor device may be manufactured according to the manufacturing method of semiconductor device according to the present embodiment. Except for the matters described above, the present embodiment is substantially the same as the first embodiment.

### Fourth Embodiment

Semiconductor Device

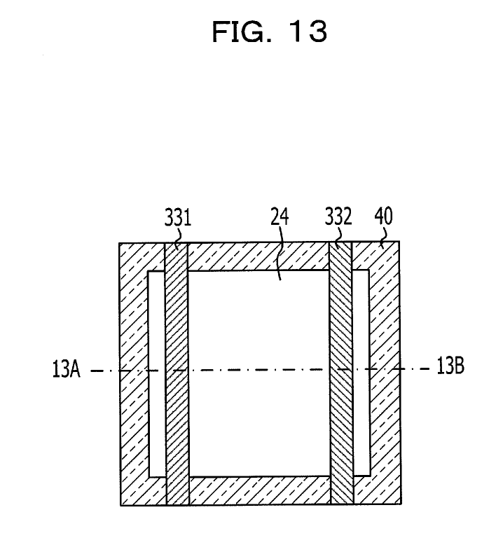

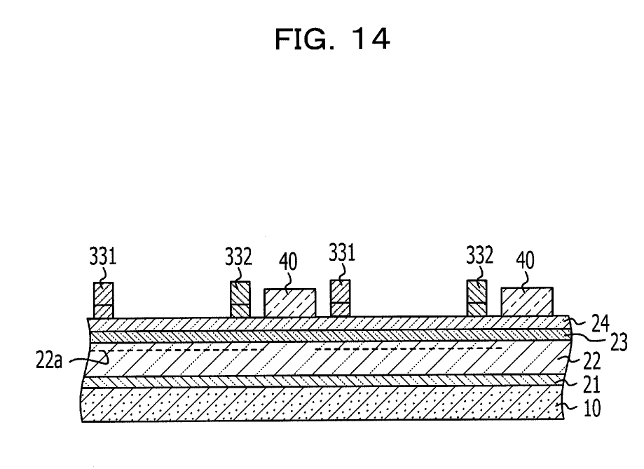

A semiconductor device according to the fourth embodiment is described with reference to FIG. 13 and FIG. 14. FIG. 13 is a top view of the semiconductor device according to the present embodiment. FIG. 14 is a cross sectional diagram including a cross section cut along a dashed-dotted line 13A-13B in FIG. 13. In the semiconductor device according to the present embodiment, a plurality of high electron mobility diodes (elements) that use nitride semiconductors are formed. This semiconductor device is composed of nitride semiconductor materials. In the semiconductor device, a buffer layer 21, an electron channel layer 22, an intermediate layer 23, an electron supply layer 24, etc., are formed on a silicon substrate 10 or the like. The buffer layer 21 is composed of AlN or the like. The electron channel layer 22 is composed of i-GaN or the like. The intermediate layer 23 is composed of i-AlGaN or the like. The electron supply layer 24 is composed of n-AlGaN or the like.

According to the above, the 2DEG 22a is produced in the intermediate layer 23 or in the electron channel layer 22 near an interface with the electron supply layer 24. The 2DEG 22a, which is produced in such a way described above, is generated due to a difference in lattice constant between the electron channel layer 22 composed of GaN and the electron supply layer 24 composed of AlGaN, etc. Alternatively, the semiconductor device according to the present embodiment may have a structure in which a cap layer (not illustrated) is additionally formed on the electron supply layer 24.

In the above semiconductor device, silicon is used for the substrate 10. However, in addition to silicon, other materials such as, but not limited to, sapphire, GaAs, SiC, GaN may also be used to form the substrate. The material forming the substrate 10 may be a semi-insulating material or a conductive material.

In the semiconductor device of the present embodiment, a cathode electrode 331 and an anode electrode 332 are formed on the electron supply layer 24, and furthermore, an isolation region formation layer 40 composed of p-GaN is formed to isolate the elements from each other. The isolation region formation layer 40 is formed on the electron supply layer 24 at a region where an element isolation region may be formed in a conventional art. Forming the p-GaN isolation region formation layer 40 enables to cause the 2DEG 22a to disappear from a region directly below the isolation region formation layer 40. Thus, by making the 2DEG 22a to disappear from a region directly below the isolation region formation layer 40, the elements may be isolated from each other. In the foregoing semiconductor device, the 2DEG 22a is produced in the electron channel layer 22 or the like. Thus, in operation, electrons work as the carriers. Accordingly, the isolation region formation layer 40 is composed of p-type semiconductor, namely p-GaN. However, in a case where the semiconductor device is operated with hole carriers, the isolation region formation layer 40 in the semiconductor device of the present embodiment may be an n-type semiconductor layer or composed of n-type semiconductor.

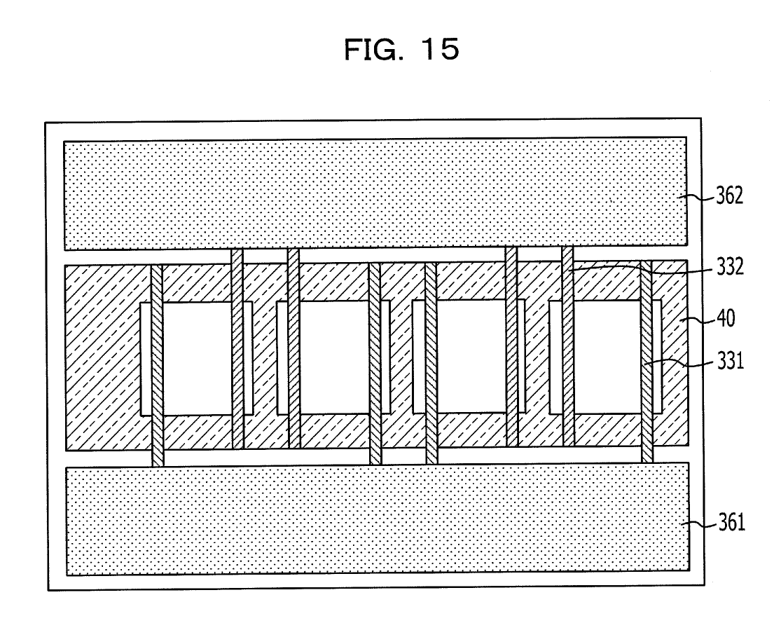

FIG. 15 illustrates a semiconductor device according to the present embodiment, in which a plurality of high electron mobility diodes (elements) are formed. An isolation region formation layer 40 is formed between the elements, and the 2DEG is caused to disappear from a region directly below the isolation region formation layer 40. Thus, the isolation of each element is achieved. In each of the high electron mobility diodes (elements), the cathode electrode 331 is connected to a cathode electrode pad 361, and the anode electrode 332 is connected to an anode electrode pad 362.

Semiconductor Device Manufacturing Method

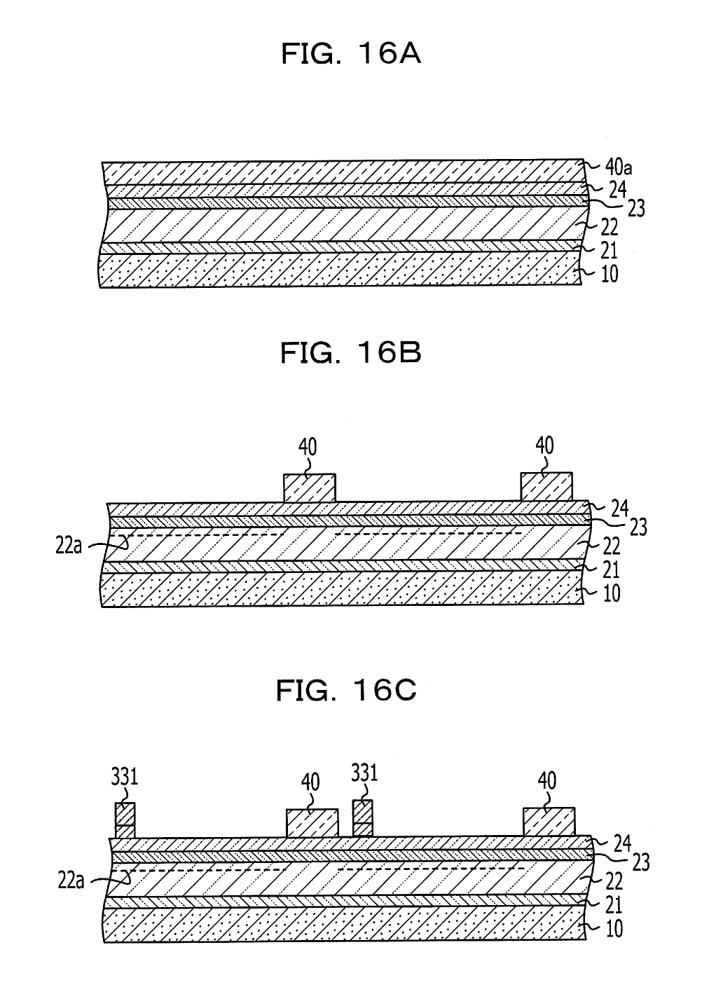

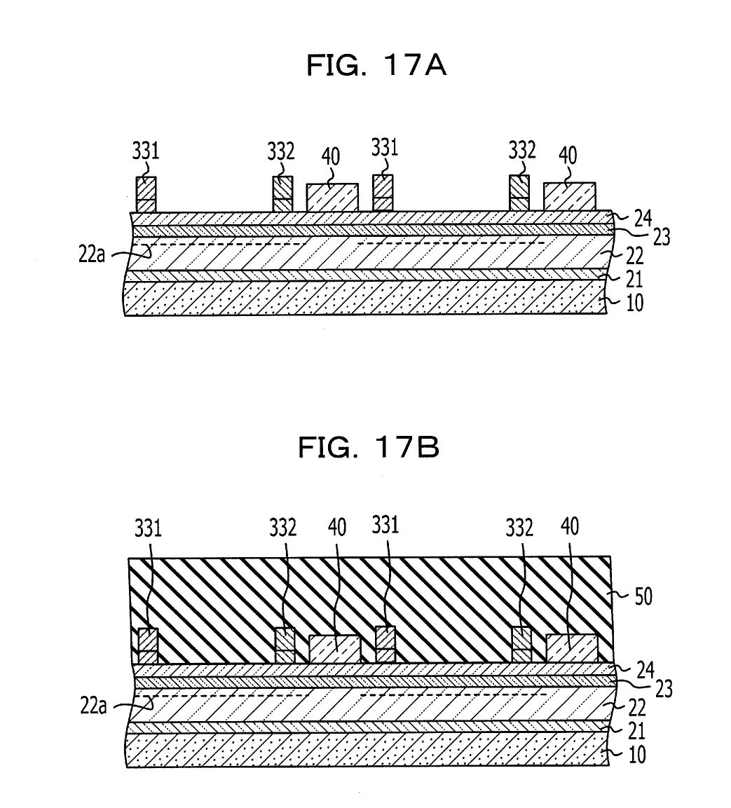

Next, a method of manufacturing the semiconductor device according to the present embodiment is described with reference to FIG. 16 and FIG. 17.

First, as illustrated in FIG. 16A, nitride semiconductor layers are formed on the substrate 10 by MOVPE technique. This nitride semiconductor layers may include, but are not limited to, the buffer layer 21, the electron channel layer 22, the intermediate layer 23, the electron supply layer 24, and an isolation region formation film 40a. The nitride semiconductor layers are epitaxially grown by MOVPE. Alternatively, a method other than MOVPE such as, for example, a MBE technique may be used. A silicon substrate is used for the substrate 10. The buffer layer 21 is composed of AlN with a thickness of 0.1 μm. The electron channel layer 22 is composed of i-GaN with a thickness of 3 μm. The intermediate layer 23 is composed of i-AlGaN with a thickness of 5 nm. The electron supply layer 24 is composed of n-AlGaN with a thickness of 30 nm. The isolation region formation film 40a is composed of p-GaN with a thickness of 10 nm. The isolation region formation film 40a is formed to form the isolation region formation layer 40, which will be described below. In an alternative structure, a cap layer (not illustrated) may be additionally formed on the electron supply layer 24.

In the present embodiment, when forming AlN, GaN, and AlGaN by MOVPE, gases such as, but not limited to, trimethylaluminium (TMA) that serves as an Al source, trimethylgallium (TMG) that serves as a Ga source, and ammonia (NH₃) that serves as a N source are used as source material gases. Layers of AlN, GaN, and AlGaN, which are nitride semiconductor layers, may be deposited by supplying the foregoing source material gases that are mixed in predetermined proportions corresponding to a composition of the nitride semiconductor layer to be deposited. For the semiconductor device according to the present embodiment, when forming the nitride semiconductor layers by MOVPE, a flow rate of the ammonia gas is 100 ccm-10 LM, an internal pressure of deposition chamber during the deposition is 50-300 torr, and a growth temperature is 1000-1200° C.

Si is used as n-type impurity to dope n-AlGaN that becomes the electron supply layer 24. Specifically, when depositing the electron supply layer 24, SiH₄ gas is added to the source material gases with a preset flow rate so as to form the Si-doped electron supply layer 24. The concentration of the doped Si in the n-AlGaN formed as described above ranges from 1×10¹⁸ to 1×10²° cm⁻³, and may be, for example, about 5×10¹⁸ cm⁻³. A method similar to the above may be employed even in a case where n-GaN or the like is deposited as the cap layer (not illustrated).

Mg is used as p-type impurity to dope p-GaN that becomes the isolation region formation film 40a. The concentration of the doped Mg ranges from 1×10²⁰ to 1×10²² cm⁻³, and may be, for example, about 1×10²¹ cm⁻³. Annealing is performed for activation after the deposition of the isolation region formation film 40a.

Next, as illustrated in FIG. 16B, the isolation region formation layer 40 for the element isolation is formed from this p-GaN. Specifically, the isolation region formation film 40a is coated with photoresist, and then subjected to exposure processing with a photolithography apparatus and development processing, thereby forming a resist pattern (not illustrated) on regions where the isolation region formation layer 40 may be formed. Subsequently, dry etching such as RIE or the like is performed to remove portions of the isolation region formation film 40a at which no resist pattern is formed, thereby forming the p-GaN isolation region formation layer 40. Subsequently, the resist pattern (not illustrate) is removed with an organic solvent or the like.

Next, as illustrated in FIG. 16C, the cathode electrodes 331 are formed on the electron supply layer 24. Specifically, the electron supply layer 24 and the isolation region formation layer 40 are coated with photoresist, and then subjected to exposure processing with a exposure apparatus and development processing, thereby forming a resist pattern (not illustrated) in which openings are formed at regions where the cathode electrodes 331 may be formed. Subsequently, a metal film for forming the cathode electrode 331 is deposited by vacuum deposition, and then dipped into an organic solvent or the like to remove the metal film deposited on the resist pattern as well as the resist pattern itself by liftoff. The remaining portions of the metal film form the cathode electrodes 331.

Next, as illustrated in FIG. 17A, the anode electrodes 332 are formed on the electron supply layer 24. Specifically, the electron supply layer 24 and the isolation region formation layer 40 are coated with photoresist, and then subjected to exposure processing with a exposure apparatus and development processing, thereby forming a resist pattern (not illustrated) in which openings are formed at regions where the anode electrodes 332 may be formed. Subsequently, a metal film for forming the anode electrodes 332 is deposited by vacuum deposition, and then dipped into an organic solvent or the like to remove the metal film deposited on the resist pattern as well as the resist pattern itself by liftoff. The remaining portions of the metal film form the anode electrodes 332.

Next, as illustrated in FIG. 17B, an insulation film 50 is formed on the electron supply layer 24, the cathode electrodes 331, the anode electrodes 332, and the isolation region formation layer 40. The insulation film 50 is a film that becomes a passivation film, and composed of an insulation material such as SiO₂, SiN or the like. The insulation film 50 is formed by plasma CVD or the like.

Thus, a semiconductor device may be manufactured according to the manufacturing method of semiconductor device according to the present embodiment. Except for the matters described above, the present embodiment is substantially the same as the first embodiment.

### Fifth Embodiment

Next, the fifth embodiment is described. The present embodiment relates to packaged semiconductor devices, a power supply apparatus, and a high frequency amplifier.

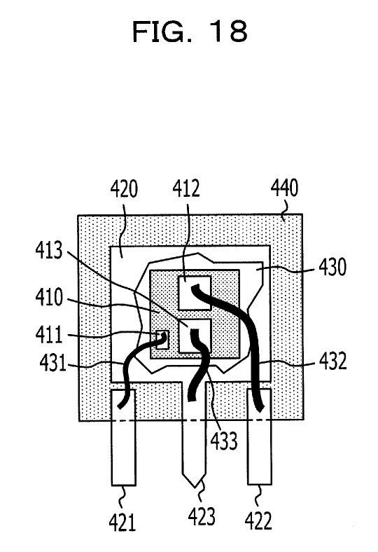

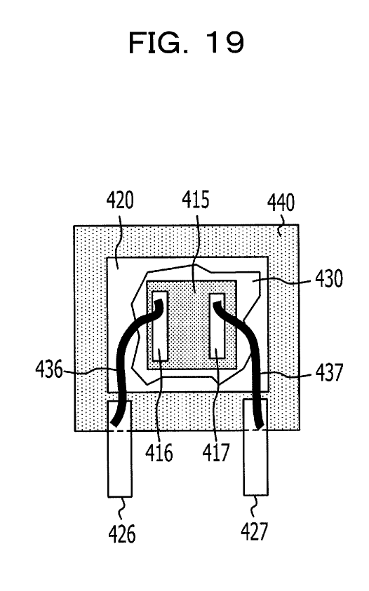

The packaged semiconductor device according to the present embodiment is formed by discretely packaging the semiconductor device according to one of the first to fourth embodiments. Such discretely packaged semiconductor devices are described with reference to FIG. 18 and FIG. 19. FIG. 18 and FIG. 19 schematically illustrate inner structures of the discretely packaged semiconductor devices, and electrode arrangements, etc., and may differ from those of the first to fourth embodiments.

Packaged Semiconductor Device 1

The packaged semiconductor device illustrated in FIG. 18 is formed by discretely packaging the semiconductor device according to one of the first to third embodiments.

First, semiconductor chips 410 that are GaN based semiconductor HEMTs are formed by cutting the semiconductor device manufactured according to one of the first to third embodiments by dicing or the like. This semiconductor chip 410 is fixed on a lead-frame 420 using a die bonding agent 430 such as solder, etc. This semiconductor chip 410 corresponds to the semiconductor device according to one of the first to third embodiments.

Next, a gate electrode 411 and a gate lead 421 are connected with a bonding wire 431, a source electrode 412 and a source lead 422 are connected with a bonding wire 432, and a drain electrode 413 and a drain lead 423 are connected with a bonding wire 433. The bonding wires 431, 432, 433 are composed of a metal material such as Al or the like. In the present embodiment, the gate electrode 411 is a kind of gate electrode pad, and connected to the gate electrode 31 of the semiconductor device according to one of the first to third embodiments. Furthermore, the source electrode 412 is a kind of source electrode pad, and connected to the source electrode 32 of the semiconductor device according to one of the first to third embodiments. The drain electrode 413 is a kind of drain electrode pad, and connected to the drain electrode 33 of the semiconductor device according to one of the first to third embodiments.

Next, resin sealing is performed with molding resin 440 by transfer molding method. Thus, the discretely packaged semiconductor device of GaN based semiconductor HEMT may be manufactured.

Packaged Semiconductor Device 2

The packaged semiconductor device illustrated in FIG. 19 is formed by discretely packaging the semiconductor device according to the fourth embodiment.

First, semiconductor chips 415 that are GaN based semiconductor diodes are formed by cutting a semiconductor device manufactured according to the fourth embodiment by dicing or the like. The semiconductor chip 415 is fixed on a lead-frame 420 using a die bonding agent 430 such as solder, etc. The semiconductor chip 415 corresponds to the semiconductor device according to the fourth embodiment.

Next, a cathode electrode 416 and a cathode lead 426 are connected with a bonding wire 436, and an anode electrode 417 and an anode lead 427 are connected with a bonding wire 437. The bonding wires 436 and 437 are composed of a metal material such as Al, etc. In the present embodiment, the cathode electrode 416 is a kind of cathode electrode pad, and connected to the cathode electrode 331 of the semiconductor device according to the fourth embodiment. Furthermore, the anode electrode 417 is a kind of anode electrode pad, and connected to the anode electrode 332 of the semiconductor device according to the fourth embodiment.

Next, resin sealing is performed with molding resin 440 by transfer molding method. Thus, the semiconductor device in which a high electron mobility diode is discretely packaged may be manufactured using GaN based semiconductor materials.

PFC Circuit, Power Supply Apparatus, and High Frequency Amplifier

Next, a PFC circuit, a power supply apparatus and a high frequency amplifier according to the present embodiment are described. The PFC circuit, the power supply apparatus, and the high frequency amplifier according to the present embodiment each use one or more of the semiconductor devices according to one or some of the first to fourth embodiments.

PFC Circuit

Next, a PFC (Power Factor Correction) circuit according to the present embodiment is described. The PFC circuit according to the present embodiment includes the semiconductor devices according to one of the first to fourth embodiments.

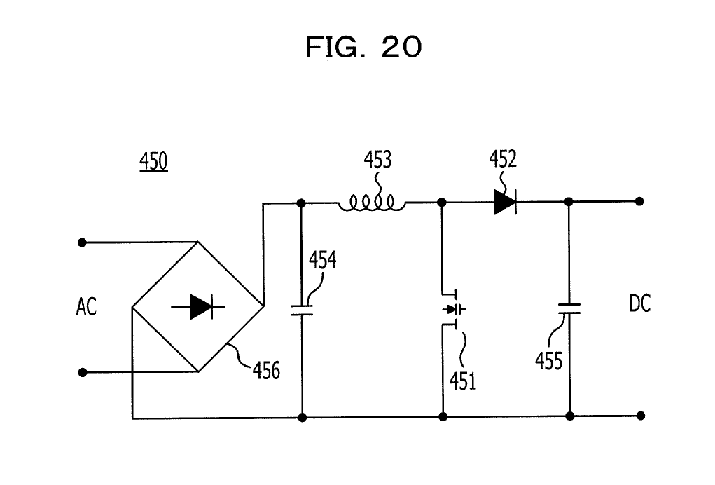

The PFC circuit according to the present embodiment is described with reference to FIG. 20. The PFC circuit 450 according to the present embodiment includes a switching element (transistor) 451, a diode 452, a choke coil 453, capacitors 454, 455, a diode bridge 456, and an alternating-current (AC) power supply (not illustrated). The switching element 451 uses a HEMT composed of AlGaN/GaN, which is the semiconductor device according to one of the first to third embodiments. Furthermore, the diode 452 uses a high electron mobility diode composed of AlGaN/GaN, which is the semiconductor device according to the fourth embodiment.

In the PFC circuit 450, a drain electrode of the switching element 451 is connected to an anode terminal of the diode 452 and one terminal of the choke coil 453. Furthermore, a source electrode of the switching element 451 is connected to one terminal of the capacitor 454 and one terminal of the capacitor 455. The other terminal of the capacitor 454 is connected to the other terminal of the choke coil 453. The other terminal of the capacitor 455 is connected to a cathode terminal of the diode 452. The AC power supply (not illustrated) is connected in between two terminals of the capacitor 454 through the diode bridge 456. The PFC circuit 450 manufactured as described above outputs a direct-current (DC) voltage across the two terminals of the capacitor 455.

The PFC circuit according to the present embodiment may improve reliability and characteristics of the PFC circuit, for it uses the semiconductor devices according to some of the first to fourth embodiments, which are highly reliable and have preferable characteristics.

Power Supply Apparatus

Next, a power supply apparatus device according to the present embodiment is described. The power supply apparatus according to the present embodiment includes HEMTs composed of AlGaN/GaN according to one of the first to third embodiments and a high electron mobility diode composed of AlGaN/GaN according to the fourth embodiment.

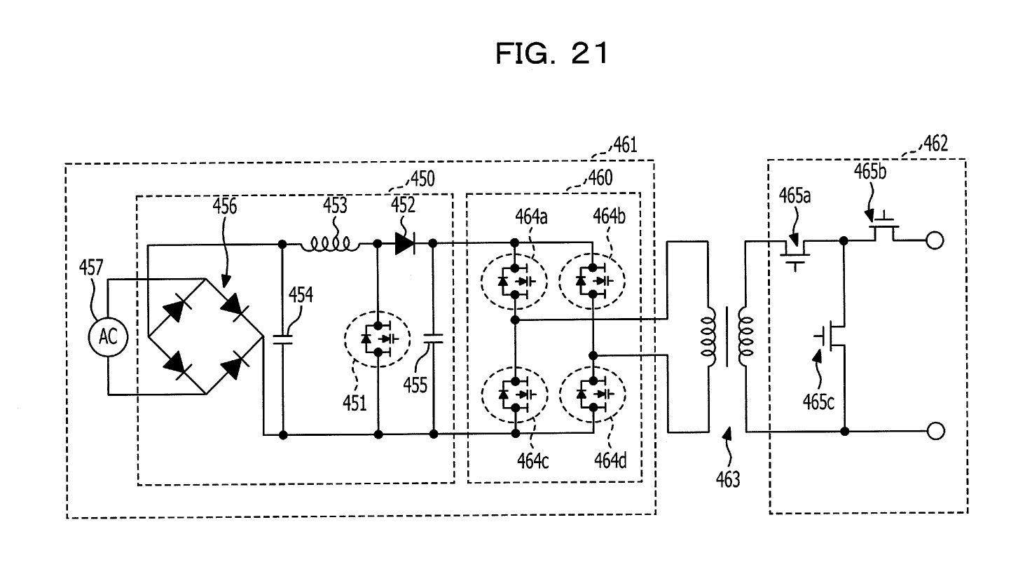

The power supply apparatus according to the present embodiment is described with reference to FIG. 21. The power supply apparatus according to the present embodiment has a structure including the foregoing PFC circuit 450 according to the present embodiment.

The power supply apparatus according to the present embodiment includes a high-voltage primary side circuit 461, a low-voltage secondary side circuit 462, and a transformer 463 provided between the primary side circuit 461 and the secondary side circuit 462.

The primary side circuit 461 includes the foregoing PFC circuit 450 according to the present embodiment and an inverter circuit connected in between two terminals of the capacitor 455 of the PFC circuit 450. This inverter circuit may be such as, for example, a full-bridge inverter circuit 460. The full-bridge inverter circuit 460 include a plurality (four switching elements in this example) of switching elements 464a, 464b, 464c, and 464d. The secondary side circuit 462 include a plurality (three in this example) of switching elements 465a, 465b, and 465c. The diode bride 456 is connected to an AC power supply 457.

In the present embodiment, the switching element 451 of the PFC circuit 450 in the primary side circuit 461 uses a HEMT composed of AlGaN/GaN, which is the semiconductor device according to one of the first to third embodiments. Furthermore, the switching elements 464a, 464b, 464c, and 464d in the full-bridge inverter circuit 460 use HEMTs composed of AlGaN/GaN, which are the semiconductor devices according to one of the first to third embodiments. On the other hands, the switching elements 465a, 465b, and 465c of the secondary side circuit 462 use FETs having a typical silicon MIS structure.

The power supply apparatus according to the present embodiment may improve reliability and characteristics of the power supply apparatus, for it uses the semiconductor devices according to some of the first to fourth embodiments, which are highly reliable and have preferable characteristics.

High Frequency Amplifier

Next, a high frequency amplifier according to the present embodiment is described. The high frequency amplifier according to the present embodiment has a structure that uses a HEMT composed of AlGaN/GaN, which is the semiconductor device according to one of the first to third embodiments.

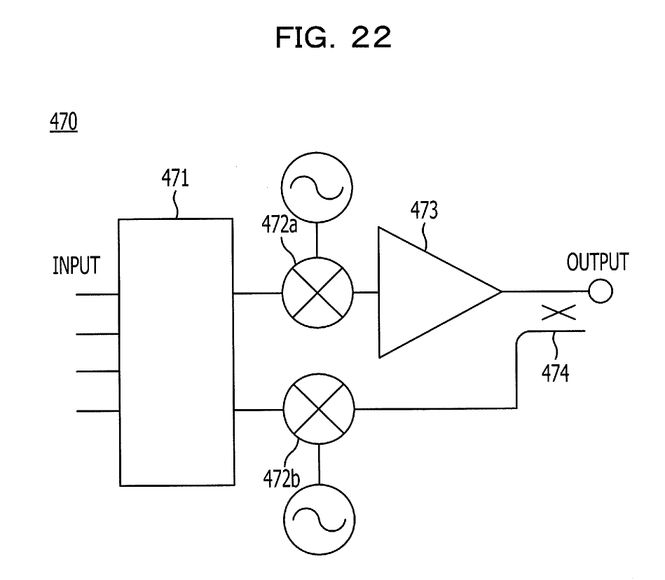

The high frequency amplifier according to the present embodiment is described with reference to FIG. 22. The high frequency amplifier according to the present embodiment includes a digital predistortion circuit 471, mixers 472a, 472b, a power amplifier 473, and a directional coupler 474.

The digital predistortion circuit 471 compensates nonlinear distortion of an input signal. The mixer 472a mixes an alternating-current (AC) signal and the input signal whose nonlinear distortion is compensated. The power amplifier 473 amplifies the input signal mixed with the AC signal, and includes a HEMT composed of AlGaN/GaN, which is the semiconductor device according to one of the first to third embodiments. The directional coupler 474 performs monitoring, etc. of the input signal or an output signal. In FIG. 22, by turning a switch, for example, a signal on the output side and the AC signal may be mixed by the mixer 472b, and the mixed signal may be sent to the digital predistortion circuit 471.

The high frequency amplifier according to the present embodiment may improve reliability and characteristics of the high frequency amplifier, for it uses the semiconductor device according to one of the first to third embodiments, which is highly reliable and have preferable characteristics.

All examples and conditional language recited herein are intended for pedagogical purposes to aid the reader in understanding the invention and the concepts contributed by the inventor to furthering the art, and are to be construed as being without limitation to such specifically recited examples and conditions, nor does the organization of such examples in the specification relate to a showing of the superiority and inferiority of the invention. Although the embodiments of the present invention have been described in detail, it should be understood that the various changes, substitutions, and alterations could be made hereto without departing from the spirit and scope of the invention.

What is claimed is:

1. A semiconductor device comprising:
a first semiconductor layer formed over a substrate;
a second semiconductor layer formed over the first semiconductor layer;
electrodes formed over the second semiconductor layer; and
a third semiconductor layer formed on the second semiconductor layer;
wherein the third semiconductor layer is formed so as to surround each element, in which the electrodes are formed, and
wherein the third semiconductor layer is a semiconductor layer of a conductivity type whose polarity is opposite to that of carriers produced in the first semiconductor layer.

2. The semiconductor device according to claim 1,
wherein the first semiconductor layer, the second semiconductor layer, and the third semiconductor layer are nitride semiconductors.

3. The semiconductor device according to claim 1,
wherein electrons are produced in the first semiconductor layer near an interface between the first semiconductor layer and the second semiconductor layer, and
wherein the third semiconductor layer is p-type.

4. The semiconductor device according to claim 1,
wherein the electrodes are a gate electrode, a source electrode, and a drain electrode, and are formed over the second semiconductor layer in a region surrounded by the third semiconductor layer.

5. The semiconductor device according to claim 4,
wherein the semiconductor device is a high electron mobility transistor.

6. The semiconductor device according to claim 1,
wherein the electrodes are a cathode electrode and an anode electrode, and are formed over the second semiconductor layer in a region surrounded by the third semiconductor layer.

7. The semiconductor device according to claim 1,
wherein the first semiconductor layer is composed of a material including GaN.

8. The semiconductor device according to claim 1,
wherein the second semiconductor layer is composed of a material including AlGaN.

9. The semiconductor device according to claim 1,
wherein the second semiconductor layer is n-type.

10. The semiconductor device according to claim 1,
wherein the third semiconductor layer is composed of a material including GaN.

11. The semiconductor device according to claim 1,
wherein an electrode is formed on the third semiconductor layer.

12. A method of manufacturing a semiconductor device, the method comprising:
sequentially layering films over a substrate, the films including formation materials for a first semiconductor layer, a second semiconductor layer, and a third semiconductor layer;
forming the third semiconductor layer by removing a portion of the film including the formation material for the third semiconductor layer; and
forming electrodes over the second semiconductor layer;
wherein the third semiconductor layer is formed so as to surround each element, in which the electrodes are formed, and
wherein the third semiconductor layer is a semiconductor layer of a conductivity type whose polarity is opposite to that of carriers produced in the first semiconductor layer.

13. The method of manufacturing a semiconductor device according to claim 12,
wherein, in the forming of electrodes, an electrode is additionally formed on the third semiconductor layer.

14. The method of manufacturing a semiconductor device according to claim 12,
wherein, in the forming of electrodes, a gate electrode, a source electrode, and a drain electrode are formed.

15. The method of manufacturing a semiconductor device according to claim 12,
wherein, in the forming of electrodes, a cathode electrode and an anode electrode are formed.

16. A method of manufacturing a semiconductor device, the method comprising:
sequentially forming and layering a first semiconductor layer and a second semiconductor layer over a substrate;
forming a mask on the second semiconductor layer, the mask including an opening at a predetermined region;
forming a third semiconductor layer on a portion of the second semiconductor layer, the portion being exposed by the opening of the mask;
removing the mask; and
forming electrodes over the second semiconductor layer;
wherein the third semiconductor layer is formed so as to surround each element, in which the electrodes are formed, and
wherein the third semiconductor layer is a semiconductor layer of a conductivity type whose polarity is opposite to that of carriers produced in the first semiconductor layer.

17. The method of manufacturing a semiconductor device according to claim 16,
wherein the mask is amorphous, and
wherein the third semiconductor layer is formed by metal-organic vapor phase epitaxy or molecular beam epitaxy.

18. The method of manufacturing a semiconductor device according to claim 16,
wherein, in the forming of electrodes, an electrode is additionally formed on the third semiconductor layer.

19. The method of manufacturing a semiconductor device according to claim 16,
wherein, in the forming of electrodes, a gate electrode, a source electrode, and a drain electrode are formed.

20. The method of manufacturing a semiconductor device according to claim 16,
wherein, in the forming of electrodes, a cathode electrode and an anode electrode are formed.
